(19) United States
(12) Patent Application Publication
(10) Pub. No.: US 2026/0122897 A1
(43) Pub. Date: Apr. 30, 2026

(54) LARGE MEMORY WINDOW VERTICAL NAND FERROELECTRIC CHARGE PUMPING FIELD EFFECT TRANSISTOR FOR HIGH-DENSITY AND LOW-POWER STORAGE

(71) Applicants: University of Notre Dame du Lac, South Bend, IN (US); The Penn State Research Foundation, University Park, PA (US)

(72) Inventors: Kai Ni, Notre Dame, IN (US); Vijaykrishnan Narayanan, State College, PA (US); Zijian Zhao, Mishawaka, IN (US); Yixin Qin, South Bend, IN (US)

(21) Appl. No.: 19/292,160

(22) Filed: Aug. 6, 2025

Related U.S. Application Data
(60) Provisional application No. 63/679,921, filed on Aug. 6, 2024.

(51) Int. Cl. H10B 43/30; G11C 16/04; H10B 51/30

(52) U.S. Cl. CPC H10B 43/30; G11C 16/0466; H10B 51/30; G11C 2216/12

(57) ABSTRACT

A nonvolatile memory device is disclosed that incorporates a FeFET having a gate stack with a ferroelectric dielectric layer positioned below a charge trapping layer. During programming, polarization switching in the ferroelectric layer drives charge injection from the gate into the overlying trapping layer. The trapped charge combines with the ferroelectric polarization to shift the threshold voltage of the device. A capping dielectric may be included above the trapping layer to improve charge retention. This gate-side charge injection mechanism supports efficient programming while maintaining a compact vertical stack suitable for integration into high-density memory architectures such as vertical NAND.

### RELATED APPLICATIONS

The present application Claims priority benefit to U.S. Provisional App. No. 63/679,921, entitled “LARGE MEMORY WINDOW VERTICAL NAND FERROELECTRIC CHARGE PUMPING FIELD EFFECT TRANSISTOR FOR HIGH-DENSITY AND LOW-POWER STORAGE,” filed Aug. 6, 2024, which is hereby incorporated herein by reference in its entirety.

### STATEMENT OF GOVERNMENT SUPPORT

This invention was made with government support under award HR0011-23-3-0002 awarded by the Defense Advanced Research Projects Agency (DARPA), and under Grant No. CCF2344819 awarded by the National Science Foundation (NSF). The government has certain rights in this invention.

### FIELD

The present disclosure relates to semiconductor memory devices, and more particularly to transistor-based nonvolatile memory technologies, including ferroelectric field effect transistors (FeFETs), for use in high-density storage architectures such as vertical NAND.

### BACKGROUND

Nonvolatile memory technologies, such as flash memory, are widely used for data storage due to their ability to retain information without power. To meet growing storage demands, vertical NAND architectures have emerged, stacking memory cells in three dimensions to increase density. In these designs, each cell typically functions as a transistor that stores data by adjusting its threshold voltage through charge trapping. However, conventional programming methods often require relatively high voltages and longer write times, which can introduce reliability and scaling challenges as device dimensions shrink and the number of layers increases. FeFETs have attracted interest as an alternative approach, using polarization switching instead of charge tunneling to store data.

### SUMMARY

Some inventive concepts described herein relate to a nonvolatile memory device that includes a transistor structure configured with a gate stack that synergistically combines a ferroelectric layer and a charge trapping layer to enhance memory window (MW) characteristics. Such a configuration may be referred to herein as a Metal-Insulator-Ferroelectric-Insulator-Semiconductor (MIFIS) structure. The gate-side charge trapping layer is positioned to receive injected charge during polarization switching of the ferroelectric material, resulting in a dynamic charge pumping effect that increases the effective MW. In some cases, the MIFIS structure achieves a 6V-8V MW using an 11V, 1 microsecond write pulse, and an 8V-12V window using a 15V, 1 microsecond pulse. This structure supports fast and energy-efficient write operations using relatively low programming voltages and short pulse durations, while also enabling immediate read-after-write functionality by suppressing unwanted channel-side charge injection. The disclosed architecture is compatible with a range of memory technologies, including but not limited to vertical NAND and multi-level cell (MLC) storage, and may utilize various ferroelectric materials, charge trapping dielectrics, and stack configurations to optimize performance, scalability, and retention.

The nonvolatile memory device can include any one or any combination of the following features. The ferroelectric layer can include hafnium-based materials, such as, but not limited to, hafnium zirconium oxide (Hf_{0.5}Zr_{0.5}O₂), and the charge trapping layer can include, but is not limited to, silicon nitride (SiNₓ) positioned between the ferroelectric layer and a metal gate electrode. The gate stack may be formed using atomic layer deposition and constrained to a total thickness compatible with vertical NAND integration (e.g., under 20 nanometers). The ferroelectric switching can act as a charge pump, dynamically injecting charge into the top trapping layer during polarization reversal events. The charge pumping effect can produce MWs exceeding 8 volts when programmed using voltage pulses of approximately 10-15 volts with durations of 1 microsecond or less. In some cases, an additional dielectric layer, such as, but not limited to, aluminum oxide (Al₂O₃), may be inserted above the charge trapping layer to further enhance charge retention and extend the MW (e.g., to 12 volts or more). The structure may enable triple-level cell (TLC) or quad-level cell (QLC) operation and is compatible with dense, stacked 3D architectures that demand low power and high endurance.

In some embodiments, the ferroelectric dielectric layer and the charge trapping layer are vertically arranged such that the ferroelectric material lies directly beneath the charge trapping layer and the gate electrode. This positioning causes polarization switching events to promote localized gate-side charge injection, which is retained in the trapping layer. The retained charge acts in conjunction with the ferroelectric polarization to induce an amplified and stable threshold voltage shift. Unlike conventional channel-side injection mechanisms that may counteract polarization switching, this vertically integrated gate-side configuration exploits the polarization field to reinforce charge storage. The result is a synergistic enhancement of the memory window that does not rely on increasing the ferroelectric layer thickness.

### BRIEF DESCRIPTION OF THE DRAWINGS

FIG. 1A illustrates a comparison between conventional flash memory, FeFET devices, and an example of a Ferroelectric Polarization-assisted Field-Effect Transistor (FePFET) architecture consistent with the present disclosure.

FIG. 1B illustrates an example of the trade-off that can arise in conventional FeFET devices between MW and the thickness of the ferroelectric layer.

FIG. 2A illustrates an example FeFET architecture.

FIG. 2B shows an example modified gate stack architecture that includes a functional layer positioned above the ferroelectric material

FIGS. 3A through 3D illustrate representative device structures and corresponding energy band diagrams for different memory configurations.

FIGS. 4A through 4C illustrate representative physical and electrical characteristics of an example FePFET-type structure in comparison with a control FeFET device having a conventional MFIS gate stack.

FIGS. 4D through 4F illustrate representative switching behavior of the example FePFET-type structure and a control MFIS-type FeFET under pulsed operation conditions.

FIGS. 5A through 5F illustrate example read stability, endurance, retention, and multi-bit storage capability of a representative FePFET-type memory device incorporating a gate-side charge trapping layer, in comparison with a baseline MFIS FeFET.

FIG. 6A illustrates an example of a nonvolatile FePFET-type memory structure incorporating a vertically stacked gate dielectric system configured to facilitate gate-side charge trapping in conjunction with ferroelectric polarization switching.

FIG. 6B illustrates the transfer characteristics of the FePFET-type memory structure 610 incorporating the gate dielectric stack shown in FIG. 6A, including a 2 nm aluminum oxide (Al₂O₃) capping dielectric layer disposed above the charge trapping layer.

FIG. 6C presents a contour map of the switching dynamics of the FePFET-type memory structure 610, illustrating the relationship between MW and programming pulse parameters.

FIG. 6D illustrates a benchmarking summary comparing the performance metrics of the FePFET-type memory structure 610 with those of four representative FeFET-based memory designs reported using alternative approaches. The comparison highlights several attributes, including total gate stack height, required write voltage, write speed, and achievable MW.

### DETAILED DESCRIPTION

### Introduction

Nonvolatile memory technologies play an important role in a wide range of electronic systems, from consumer devices to data storage infrastructure. Among these, flash memory has been widely adopted due to its ability to retain information without power and its compatibility with high-volume manufacturing processes. Flash memory continues to be widely used due to its scalability and compatibility with high-density, high-volume manufacturing. Vertical NAND flash, in particular, has emerged as a backbone of modern storage architectures by offering high capacity through stackable cell arrangements that efficiently utilize footprint.

As demand for higher storage capacities continues to grow, memory architectures have evolved to include three-dimensional (3D) integration, such as vertical NAND. In these structures, memory cells are arranged in vertical stacks, allowing more data to be stored in a given footprint. Typically, each memory cell functions as a transistor whose threshold voltage can be adjusted by storing electrical charge in a gate-adjacent layer. Depending on the amount of charge, different logic states can be represented. However, despite its density advantage, vertical NAND continues to face inherent limitations in write performance. Because conventional flash memory relies on charge injection via tunneling mechanisms, the process often requires high write voltages and long programming pulses, which can negatively impact speed, power efficiency, and long-term endurance.

In conventional flash designs, programming the memory cell often involves moving electrons through a thin oxide layer into a floating gate or charge-trapping material. This process generally requires relatively high voltages and longer programming times. As more layers are added in vertical stacks, maintaining electrical separation and consistent performance across the structure can become more complex, especially when high voltage levels are used. In addition, repeated high-voltage programming can degrade the oxide layer and reduce the endurance of flash cells. Charge leakage and variability across stacked layers may also impact data retention and long-term reliability, especially in dense 3D NAND arrays. Furthermore, the use of high programming voltages (e.g., around 20 volts) and long pulse durations (e.g., milliseconds) in densely stacked structures can lead to dielectric breakdown between adjacent layers, thereby complicating further device scaling. These constraints collectively present ongoing challenges for continued scaling and efficiency in flash-based memory.

To increase data density, many flash memories support multi-level cell (MLC) operation, where each cell holds more than one bit of data. This approach relies on the ability to clearly distinguish between multiple threshold voltage levels within each transistor. As a result, the range between programmed states—commonly referred to as the MW—can influence overall device behavior. Maintaining this range over time, and across process and usage conditions, is often a subject of investigation in memory design. As threshold levels become more closely spaced in higher-bit-per-cell designs, distinguishing between them becomes increasingly sensitive to noise, process variation, and charge drift over time. In some cases, multi-level schemes such as triple-level cell (TLC) and quad-level cell (QLC) encoding may be employed, further tightening voltage margins and amplifying the need for stable and sufficiently wide MWs.

Other memory designs, such as those using ferroelectric materials within the transistor gate stack, have been explored as alternatives to traditional charge-based storage. These devices rely on polarization switching rather than charge tunneling to shift the threshold voltage. Ferroelectric field effect transistors (FeFETs) can offer efficient switching behavior and reduced programming voltages, although the achievable MW is often influenced by material thickness and stack design. Balancing these factors while maintaining compact device dimensions and compatibility with vertical integration remains an area of continued development. However, the MW in FeFETs tends to scale linearly with the thickness of the ferroelectric layer, limiting the achievable window when thin layers are required for high-density integration. As a result, maintaining a stable and distinguishable MW becomes more difficult, especially as threshold levels are packed more tightly.

To address these or other limitations, some aspects of the inventive concepts described herein relate to memory structures that combine ferroelectric switching with gate-side charge injection. In certain embodiments, a functional layer may be positioned above the ferroelectric material to facilitate the trapping of injected charge during polarization switching. This interaction can help amplify the effective threshold voltage shift, potentially enabling a wider MW with reduced dependence on ferroelectric thickness. This general concept underlies the FePFET architectures described herein, which may offer advantages in balancing MW, write performance, and integration scalability.

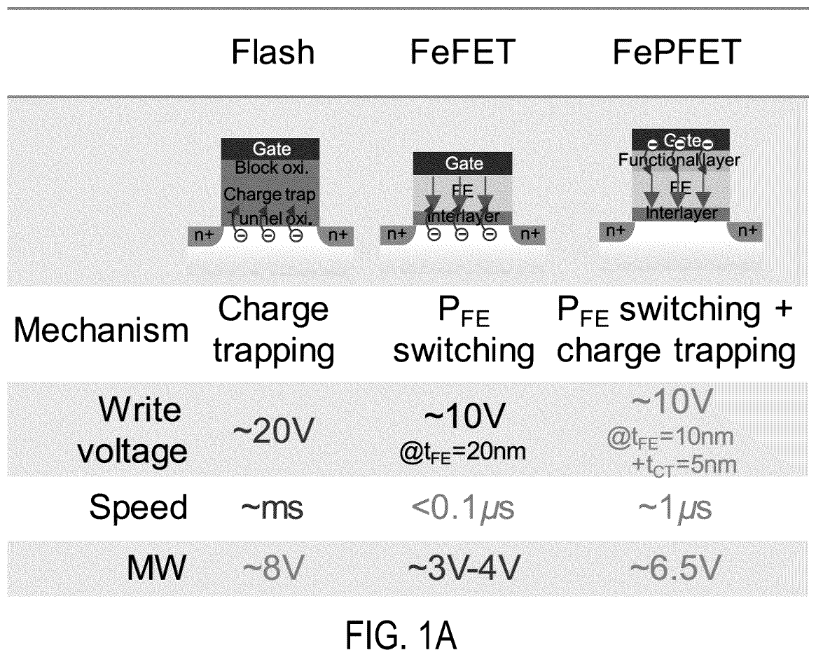

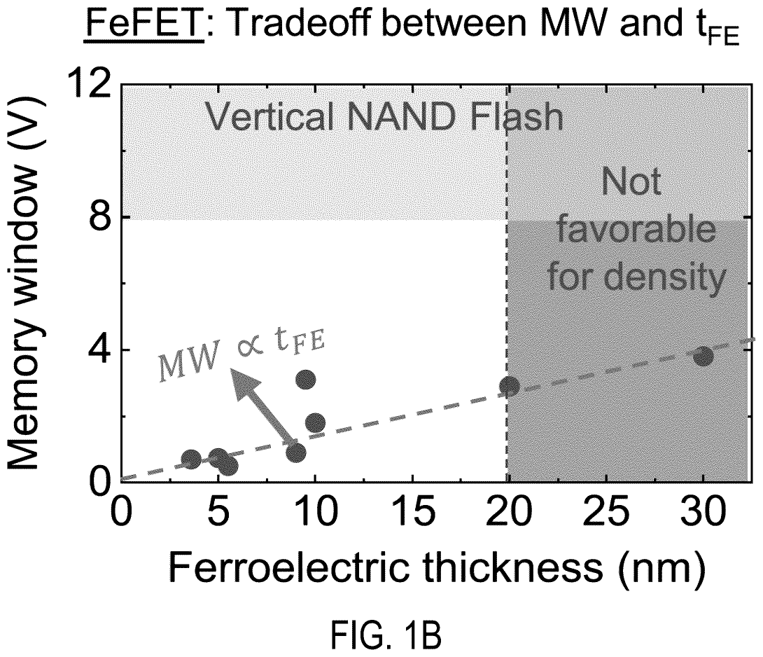

FIG. 1A illustrates a comparison between conventional flash memory, FeFET devices, and an example of a FePFET architecture consistent with the present disclosure. Each column in the diagram presents a representative gate stack configuration and summarizes performance characteristics, including switching mechanism, write voltage, switching speed, and MW.

The left column corresponds to a conventional flash memory cell. This structure typically includes a tunneling oxide, a charge-trapping layer, and a blocking oxide beneath a gate electrode. Programming is often achieved through charge injection via tunneling into the trapping layer, a process that generally requires relatively high voltages (e.g., ˜20 V) and long pulse durations (e.g., on the order of milliseconds). While such flash devices can exhibit a relatively wide MW (e.g., ˜8 V), the high voltage and slow write speed can introduce endurance concerns and scaling limitations, particularly in three-dimensional vertical NAND structures.

The center column shows a traditional FeFET structure, which utilizes a ferroelectric (FE) layer and an interfacial layer (IL) within the gate stack. These devices often operate through ferroelectric polarization switching, offering faster switching behavior (e.g., <0.1 μs) and lower programming voltages (e.g., ˜10 V for t_{FE} (thickness of the ferroelectric layer)=20 nm) compared to conventional flash. However, the MW in such FeFETs is typically limited (e.g., ˜3-4 V), and tends to scale linearly with the ferroelectric thickness, which can constrain density in vertically integrated arrays.

The right column depicts an illustrative embodiment of a FePFET architecture in accordance with some aspects of the inventive concepts. In this example, the gate stack includes a ferroelectric layer and an interlayer similar to FeFETs, but also includes a functional layer above the ferroelectric material that serves as a charge trapping layer to facilitate gate-side charge storage. This configuration can enable a combined mechanism of ferroelectric switching and gate-driven charge injection, allowing charge to be dynamically pumped into the trapping layer during polarization reversal. As shown, this architecture can support write voltages around 10 V (e.g., for t_{FE}=10 nm and thickness of the charge trapping layer t_{CT}=5 nm), write speeds on the order of 1 μs, and an enhanced MW (e.g., ˜6.5 V). It should be understood that the materials, layer thicknesses, and stack sequences illustrated in this example are non-limiting, and that other configurations falling within the scope of the disclosed architecture may be employed to achieve comparable benefits in memory performance, scalability, and integration compatibility.

FIG. 1B illustrates an example of the trade-off that can arise in conventional FeFET devices between MW and the thickness of the ferroelectric layer (t_{FE}). As shown, the MW generally increases with increasing ferroelectric thickness, reflecting the dependence of polarization-driven threshold voltage shifts on the amount of switchable dipole material. In many cases, this relationship approximates a linear trend.

However, increasing t_{FE} beyond approximately 20 nanometers can become less favorable for integration into high-density memory architectures. For example, in vertical NAND configurations, it is often desirable to limit total gate stack thickness in order to support tight pitch scaling, high aspect ratio structures, and process compatibility. As such, very thick ferroelectric layers may pose challenges in terms of fabrication, device reliability, or integration density.

In typical FeFETs with ferroelectric thicknesses below this threshold, the resulting MW may fall short of what is needed for certain multi-level storage applications. This trade-off, between achieving a sufficiently large MW and maintaining a compact device footprint, represents a constraint in conventional FeFET scaling. Addressing these or other challenge provides motivation for alternative architectures, such as the FePFET designs described herein, which can enhance the effective MW without relying on thicker ferroelectric layers.

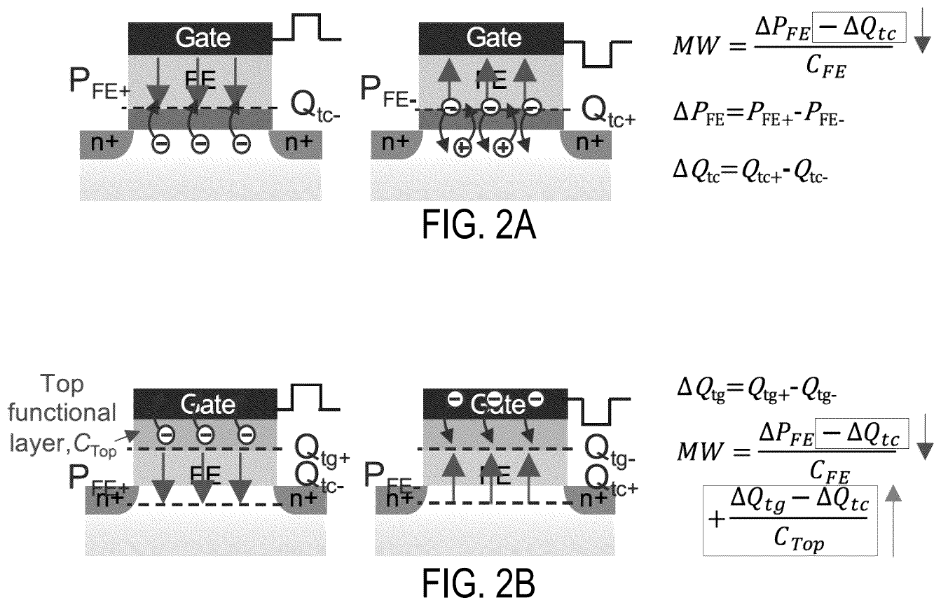

FIG. 2A illustrates an example FeFET architecture, in which the device switching behavior may be influenced by interactions between ferroelectric polarization and charge trapping phenomena. As shown, polarization reversal within the ferroelectric layer P_{FE} can be accompanied by charge injection from the channel-side into a charge trapping region Q_{tc}. This channel-side charge movement may partially offset the effect of polarization switching on the device threshold voltage, as captured by the shown expression for the MW. In some implementations, this offset can constrain the effective MW, as the net threshold shift is reduced by the contribution from ΔQ_{tc}.

FIG. 2B shows an example modified gate stack architecture that includes a functional layer positioned above the ferroelectric material. In some cases, this additional functional layer may facilitate gate-side charge trapping (Q_{tg}) during polarization switching. The trapped charge may contribute to a larger net change in threshold voltage, supplementing the ferroelectric response. As depicted, the MW expression reflects the combined effects of both the ferroelectric polarization and the gate-side trapped charge, modulated by the respective capacitances (C_{FE}, C_{TOP}). Compared to other structures such as that shown in FIG. 2A, this approach may allow for an expanded MW, improving write efficiency and scalability while maintaining compact device geometries. In some cases, this interaction may be described as a form of ferroelectric charge pumping, in which polarization switching assists charge injection into the top functional layer. The depicted configuration of FIG. 2B represents a non-limiting example of a FePFET-type structure in accordance with the disclosed inventive concepts, where ferroelectric switching may serve to assist charge injection into the top functional layer, thereby enhancing the threshold shift.

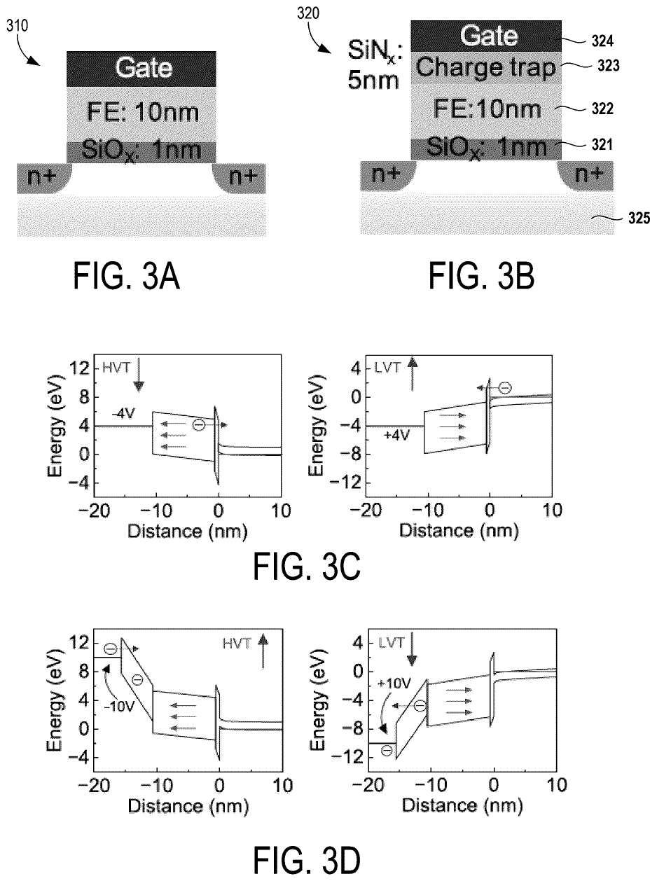

FIGS. 3A through 3D illustrate representative device structures and corresponding energy band diagrams for different memory configurations, including an example FeFET-type structure 310 and an example FePFET-type structure 320 consistent with aspects of the present disclosure. As shown in FIG. 3A, the FeFET-type structure 310 includes a gate stack including a FE layer positioned over an interfacial layer (e.g., SiOₓ), such as in a conventional MFIS (Metal-Ferroelectric-Insulator-Semiconductor) arrangement.

FIG. 3B illustrates an example of a nonvolatile FePFET-type memory structure 320, configured to utilize gate-side charge injection in conjunction with ferroelectric switching to enhance MW performance. The FePFET-type memory structure 320 may be implemented on a semiconductor substrate 325 that includes doped source and drain regions formed within or on the surface of a semiconductor body. A vertically stacked gate dielectric structure is disposed between the channel region and a gate electrode, and may include, in order from bottom to top: an interfacial dielectric layer 321, a ferroelectric dielectric layer 322, a charge trapping layer 323, and a gate electrode 324. The nonvolatile FePFET-type memory structure 320 may be an embodiment of, or otherwise include one or more features of, the nonvolatile FePFET-type memory structure 600, including but not limited to layer configurations, material compositions, or functional attributes described herein.

The semiconductor substrate 325, as shown in FIG. 3B, can be configured to support the formation and operation of the FePFET-type memory structure 320. The substrate 325 can be formed from a semiconductor material, including but not limited to P-type silicon, N-type silicon, or silicon-on-insulator (SOI) platforms. Doped source and drain regions can be introduced into the substrate through ion implantation techniques, such as phosphorus or boron implantation, followed by thermal annealing for dopant activation. The channel region can be formed in the undoped or lightly doped region between the source and drain. In some embodiments, the substrate may further include well structures or isolation features to support device scalability or array-level integration. The choice of substrate material and doping profile can be tuned to influence threshold voltage behavior, carrier mobility, and electrostatic coupling with the overlying gate stack layers.

The interfacial dielectric layer 321 is located adjacent to the semiconductor substrate 325 and beneath the ferroelectric dielectric layer 322. The interfacial dielectric layer 321 may serve multiple purposes, including facilitating a high-quality interface, suppressing interfacial charge traps, and/or promoting stable polarization switching. Materials suitable for the interfacial dielectric layer 321 may include, but are not limited to, silicon oxide (SiOₓ), silicon oxynitride (SiON), aluminum oxide (Al₂O₃), hafnium oxide (HfO₂), lanthanum oxide (La₂O₃), yttrium oxide (Y₂O₃), zirconium oxide (ZrO₂), or other high-k dielectric materials, alone or in combination. In some embodiments, a composite or graded stack may be employed, such as SiON/Al₂O₃ or SiON/HfO₂ to engineer band alignment and interfacial dipoles. In some cases, the interfacial dielectric layer 321 may be thermally grown or deposited using atomic layer deposition (ALD) or chemical vapor deposition (CVD). The thickness of the interfacial dielectric layer 321 may range from about 0.5 nm to 2.0 nm. In the embodiment illustrated in FIG. 3B, the interfacial dielectric layer 321 includes approximately 1 nm of SiOₓ.

Positioned above the interfacial dielectric layer 321 is a ferroelectric dielectric layer 322, which can provide the polarization-based switching functionality. The ferroelectric dielectric layer 322 may include, but is not limited to, hafnium zirconium oxide (Hf₁₋ₓZrₓO₂) where 0≤x≤1, or doped hafnium oxides such as Si:HfO₂, Al:HfO₂, Y:HfO₂, Gd:HfO₂, Sr:HfO₂, La:HfO₂, or Sc:HfO₂. Other ferroelectric oxides such as ZrO₂, HfTiOₓ, or mixed-metal fluorites may also be used. The thickness may range from approximately 5 nm to 15 nm. In the embodiment shown, the ferroelectric dielectric layer 322 includes Hf_{0.5}Zr_{0.5}O₂ with a thickness of approximately 10 nm. The ferroelectric dielectric layer 322 may be deposited via ALD, sputtering, or CVD and may undergo post-deposition thermal annealing to crystallize the material into the desired ferroelectric orthorhombic phase.

Located above the ferroelectric dielectric layer 322 is a charge trapping layer 323 configured to trap electrons or holes injected from the gate side during polarization switching events. The charge trapping layer 323 may include materials such as, but not limited to, silicon nitride (SiNₓ), aluminum nitride (AlN), hafnium oxide (HfO₂), tantalum oxide (Ta₂O₅), zirconium oxide (ZrO₂), aluminum oxide (Al₂O₃), or composite materials such as SiN/Al₂O₃, nanolaminates, or wide-bandgap dielectrics capable of forming and maintaining charge storage sites. In the configuration of FIG. 3B, the charge trapping layer 323 includes SiN, with a nominal thickness of about 5 nm. The charge trapping layer 323 may be deposited using ALD, plasma-enhanced chemical vapor deposition (PECVD), or low-pressure CVD. The trapped charges may reinforce the polarization-induced threshold voltage shift, leading to an amplified and stable MW without requiring increased ferroelectric thickness.

The gate electrode 324 overlies the charge trapping layer 323 and may serve as the control terminal for inducing switching and injection. The gate electrode 324 may include metals or metal-based compounds such as, but not limited to, tungsten (W), titanium nitride (TiN), or tantalum nitride (TaN), and may be deposited via physical vapor deposition (PVD), ALD, or CVD. The material of the gate electrode 324 may be selected to optimize work function alignment and electrostatic control of the underlying channel, while also enabling efficient write and erase cycling for nonvolatile memory operation.

Compared to FIG. 3A, FIG. 3B illustrates a related configuration in which a charge trapping layer (e.g., SiNₓ) is further included above the ferroelectric material. This configuration may correspond to an example MIFIS (Metal-Insulator-Ferroelectric-Insulator-Semiconductor) structure, and may enable gate-side charge trapping during ferroelectric switching events.

FIGS. 3C and 3D depict TCAD-simulated energy band diagrams corresponding to the structures shown in FIGS. 3A and 3B, respectively, under representative programming conditions. In the configuration of FIG. 3C, the application of a negative gate voltage during a reset operation causes electrons to be repelled from the ferroelectric layer toward the channel, resulting in a high threshold voltage (HVT) state. Conversely, a positive gate voltage during a set operation attracts electrons from the channel toward the ferroelectric layer, establishing a low threshold voltage (LVT) state. These operations may lead to partial cancellation of the polarization effect by channel-side charge injection, which may constrain the achievable MW.

In contrast, the configuration illustrated in FIG. 3D includes a charge trapping layer disposed between the ferroelectric material and the gate electrode. In some cases, application of a negative gate voltage may cause electrons to be injected from the gate into the charge trapping layer and retained therein. When a positive gate voltage is subsequently applied, the trapped charge may be detrapped toward the gate, modifying the device threshold voltage in conjunction with the ferroelectric polarization state. As shown, the combined effect of ferroelectric switching and gate-side charge trapping may produce a wider separation between HVT and LVT states. This phenomenon may be viewed as a form of ferroelectric-assisted charge injection or charge pumping, and may contribute to enhanced MW characteristics, improved retention, and reduced sensitivity to channel-side injection.

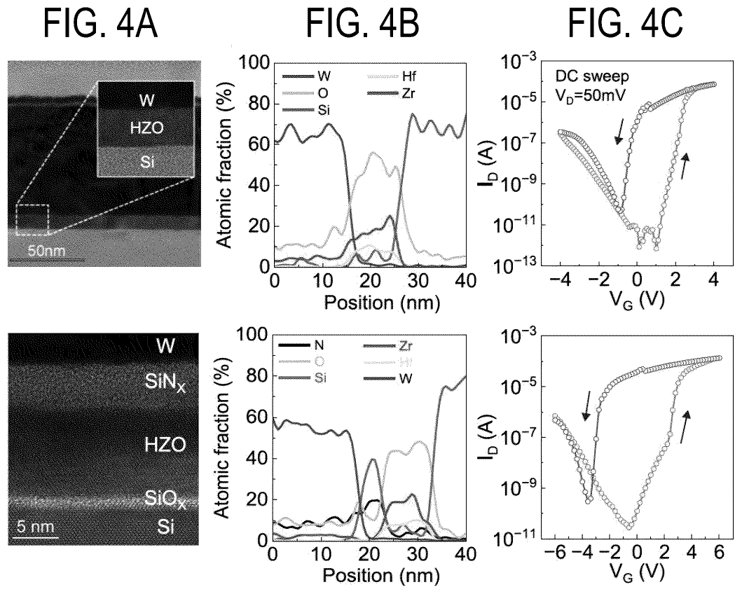

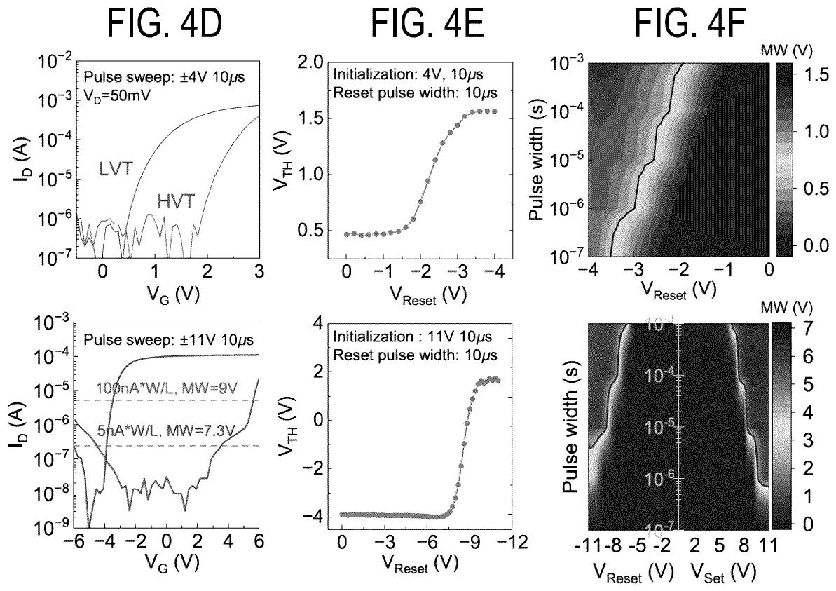

FIGS. 4A through 4C illustrate representative physical and electrical characteristics of an example FePFET-type structure in comparison with a control FeFET device having a conventional MFIS gate stack.

FIG. 4A presents cross-sectional transmission electron microscopy (TEM) images of both gate stack configurations. In the upper image, the control structure includes a ferroelectric layer (e.g., Hf_{0.5}Zr_{0.5}O₂ or HZO) formed over an interfacial layer (e.g., SiOₓ) on a semiconductor substrate. In the lower image, an alternative structure includes a charge trapping layer (e.g., SiNₓ) positioned above the ferroelectric layer, beneath a gate electrode. These images confirm the physical integration of the respective layers within the stack.

The device fabrication process may begin on a P-type silicon substrate. A screen oxide is deposited to facilitate phosphorus ion implantation, followed by thermal activation. The gate region is opened by removing isolation oxide, after which a 10 nm ferroelectric Hf_{0.5}Zr_{0.5}O₂ layer and a 5 nm silicon nitride (SiNₓ) charge trapping layer are deposited using atomic layer deposition (ALD) at approximately 250° C. Source and drain vias are formed using reactive-ion etching (RIE) and buffered oxide etch (BOE). A 100 nm thick tungsten (W) layer is deposited by sputtering to serve as source, drain, and gate electrodes. Post-metallization annealing is performed in forming gas (N₂+H₂) at 350° C. and in nitrogen (N₂) at 500° C. to induce ferroelectric crystallization. The control device does not include the SiNₓ deposition.

FIG. 4B depicts corresponding elemental profiles obtained along a vertical line scan of the gate stack, showing atomic concentrations of constituent elements (e.g., Hf, Zr, O, Si, N, W) at different depths. The presence of H₂O and SiOₓ is confirmed in both configurations, while the additional nitrogen and associated compositional changes in the lower graph are consistent with the inclusion of a SiNₓ charge trapping layer in the FePFET-type structure. These profiles may assist in verifying material presence, layer boundaries, and stack uniformity.

FIG. 4C shows representative I_{D}-V_{G} characteristics for both configurations under DC gate sweeps. Both devices exhibit counterclockwise hysteresis, which is generally indicative of polarization switching behavior with minimal channel-side charge injection. The structure incorporating the charge trapping layer demonstrates a wider hysteresis window, suggesting a more pronounced threshold voltage shift and correspondingly larger MW. These electrical characteristics are consistent with gate-side charge storage reinforcing the ferroelectric response.

FIGS. 4D through 4F illustrate representative switching behavior of the example FePFET-type structure and a control MFIS-type FeFET under pulsed operation conditions. The measurements were performed using transistors with a channel width-to-length (W/L) ratio of 50 μm/1 μm.

FIG. 4D shows the drain current (I_{D}) versus gate voltage (V_{G}) response following application of positive and negative write pulses (set/reset) for both the control and FePFET-type configurations. The control device exhibits a relatively narrow separation between the low-V_{TH} (LVT) and high-V_{TH} (HVT) states, resulting in a limited MW. In contrast, the FePFET-type structure, incorporating a gate-side charge trapping layer, demonstrates an increased threshold separation (e.g., ˜7.3-9.0 V MW) depending on the extraction current criteria. This enhancement is consistent with effective charge trapping and retention in the gate-side functional layer. It is noted that the noise floor is elevated due to the high current measurement range used to visualize the full on-state current.

FIG. 4E depicts the extracted threshold voltage (V_{TH}) as a function of applied reset voltage for a fixed pulse width. The FePFET-type device exhibits a sharp and saturated transition in V_{TH} at relatively moderate reset voltages, indicating a highly efficient write process. This behavior suggests strong polarization-assisted charge trapping dynamics, facilitating well-defined memory states without requiring excessive write amplitude.

FIG. 4F presents two-dimensional maps of the MW as a function of pulse amplitude and pulse width. For the control device, the achievable MW remains below ˜1.5 V across the tested operating space. In contrast, the FePFET-type structure exhibits a significantly broader and more tunable MW landscape, exceeding 7 V under certain conditions. These plots demonstrate that the FePFET-type architecture can achieve robust switching and high MW across a range of programming conditions, further highlighting the effectiveness of gate-side charge storage in enhancing device performance.

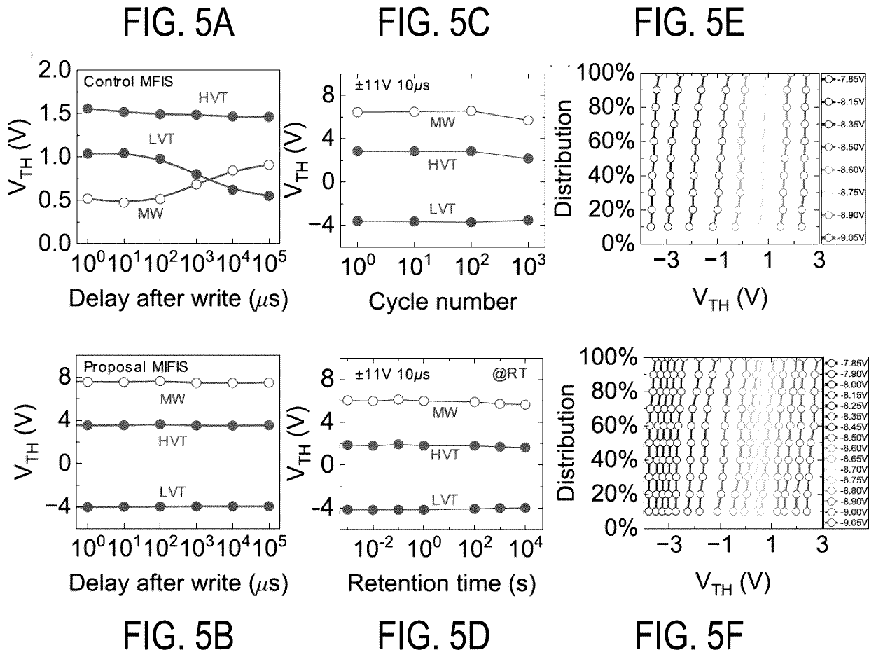

FIGS. 5A through 5F illustrate the read stability, endurance, retention, and multi-bit storage capability of a representative FePFET-type memory device incorporating a gate-side charge trapping layer, in comparison with a baseline MFIS FeFET. The measurements shown were taken from devices having a W/L ratio of 50 μm/1 μm.

FIGS. 5A and 5B show the extracted threshold voltage (V_{TH}) states—corresponding to HVT, LVT, and their associated MW—as a function of delay between write and read operations. As illustrated in FIG. 5A, the control MFIS device exhibits significant threshold voltage relaxation over time following the write pulse, particularly for the LVT state, thereby narrowing the MW and requiring a read delay for stabilization. In contrast, the example FePFET-type structure (FIG. 5B) shows a substantially time-invariant response, indicating immediate read-after-write capability. This behavior is consistent with suppression of channel-side injection and improved stabilization through gate-side charge storage.

FIG. 5C presents cycling endurance characteristics for the FePFET-type device subjected to ±11 V, 10 μs write pulses. The HVT and LVT states, as well as the MW, remain stable across 1000 programming cycles, suggesting robust polarization switching and charge trapping behavior under repeated operation.

FIG. 5D illustrates retention performance over a range of time scales up to 10\hat{ }4 seconds, measured at room temperature. The V_{TH} levels and MW of the FePFET-type structure remain largely constant, further confirming that trapped charges in the gate-side functional layer are reliably held, with negligible degradation or drift over time.

FIGS. 5E and 5F demonstrate the multi-bit storage capability of the FePFET-type memory through extraction of distinct threshold voltage distributions. FIG. 5E shows the feasibility of storing at least three distinct logic levels (triple-level cell, TLC), while FIG. 5F depicts separation of four levels (quad-level cell, QLC). The narrow distribution widths and distinct peak separations in both figures suggest that the device supports high-precision threshold control, enabled by the expanded and stable MW achieved through ferroelectric-assisted charge trapping.

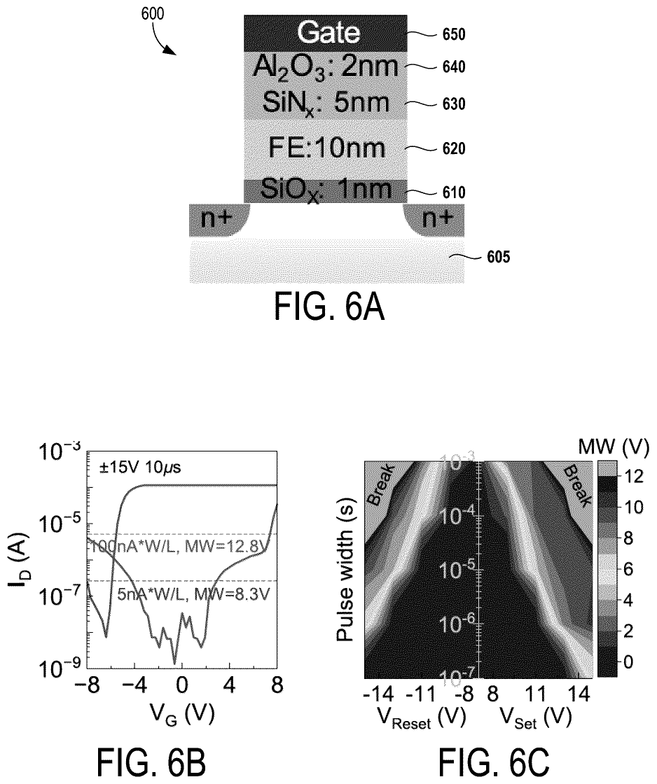

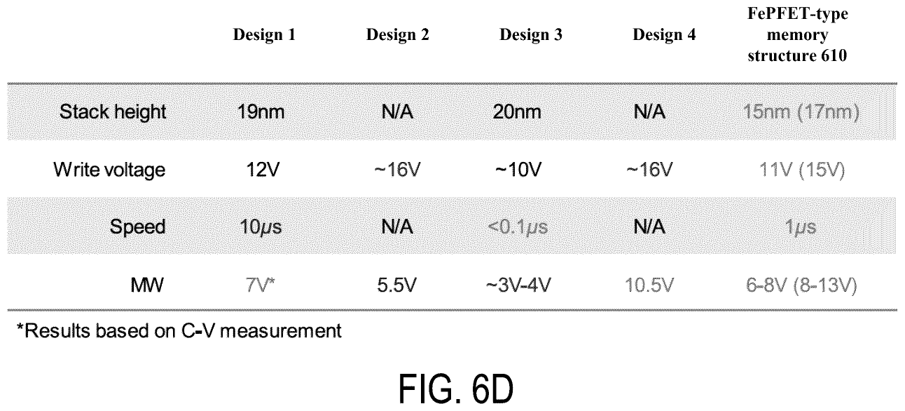

FIG. 6A illustrates an example of a nonvolatile FePFET-type memory structure 600 incorporating a vertically stacked gate dielectric system configured to facilitate gate-side charge trapping in conjunction with ferroelectric polarization switching. The FePFET-type memory structure 610 may be fabricated on a semiconductor substrate 605 having doped source and drain regions formed within or on the surface of a semiconductor body. Above the substrate 605, a sequence of insulating and functional layers may be disposed between the semiconductor channel and the gate electrode. The gate stack includes, in order from bottom to top: an interfacial dielectric layer 610, a ferroelectric dielectric layer 620, a charge trapping layer 630, a capping dielectric layer 640, and a gate electrode 650. The nonvolatile FePFET-type memory structure 600 may be an embodiment of, or otherwise include one or more features or layers of, the nonvolatile FePFET-type memory structure 320, including but not limited to structural elements, material selections, or operational characteristics described herein.

The lowermost gate dielectric in the FePFET-type memory structure 610 is the interfacial dielectric layer 610, disposed between the ferroelectric layer 620 and the underlying semiconductor substrate 605. The interfacial dielectric layer 610 may serve to provide proper band alignment, suppress interfacial trap states, and/or promote uniform ferroelectric switching. The interfacial dielectric layer 610 may include, but is not limited to, silicon oxide (SiOₓ), silicon oxynitride (SiON), or aluminum oxide (Al₂O₃). In some embodiments, the interfacial dielectric layer 610 may have a thickness in the range of approximately 0.5 nm to 2.0 nm. A thickness of approximately 1.0 nm of SiOₓ is used in the illustrated example. The interfacial dielectric layer 610 may be thermally grown or deposited using plasma-enhanced chemical vapor deposition (PECVD) or atomic layer deposition (ALD).

Above the interfacial dielectric layer 610 is a ferroelectric dielectric layer 620, which may serve as the primary medium for polarization-based charge storage. The ferroelectric dielectric layer 620 may include hafnium-based oxides such as, but not limited to, hafnium zirconium oxide (Hf₁₋ₓZrₓO₂), where x ranges from 0 to 1, or doped variants such as HfO₂ doped with silicon (Si), aluminum (Al), yttrium (Y), or lanthanum (La). In some cases, the ferroelectric dielectric layer 620 includes Hf_{0.5}Zr_{0.5}O₂. The ferroelectric dielectric layer 620 may be deposited using ALD, sputtering, or chemical vapor deposition (CVD), and may have a thickness in the range of about 5 nm to 15 nm. A nominal thickness of 10 nm is illustrated in FIG. 6A. The ferroelectric dielectric layer 620 may be crystallized via thermal annealing in a nitrogen, argon, or forming gas ambient to induce the orthorhombic phase necessary for ferroelectricity.

Overlying the ferroelectric dielectric layer 620 is a charge trapping layer 630 configured to store injected carriers from the gate during switching events. The charge trapping layer 630 may include, but is not limited to, silicon nitride (SiNₓ), aluminum nitride (AlN), hafnium oxide (HfO₂), or multilayer composites thereof. Silicon nitride is used in the present example, with a nominal thickness of approximately 5 nm. The charge trapping layer 630 may be formed using ALD, low-pressure chemical vapor deposition (LPCVD), or plasma-enhanced deposition techniques. The thickness may range from about 2 nm to 8 nm. The trapped charges in the charge trapping layer 630 assist in stabilizing the threshold voltage shifts caused by the ferroelectric polarization, contributing to an expanded and more tunable MW.

Disposed above the charge trapping layer 630 is a capping dielectric layer 640, which may function as a tunnel barrier, leakage suppression barrier, and/or field-shaping layer. The capping dielectric layer 640 may include, but is not limited to, aluminum oxide (Al₂O₃), hafnium oxide (HfO₂), zirconium oxide (ZrO₂), silicon oxide (SiOₓ), titanium oxide (TiO₂), or lanthanum oxide (La₂O₃), or high-k dielectric materials. Composites or laminated structures, such as Al₂O₃/HfO₂ or SiON/Al₂O₃, may be used to tune electric field distribution or injection barriers. The thickness of the capping dielectric layer 640 may range from about 1 nm to 5 nm, depending on desired tunneling characteristics and gate capacitance. In the embodiment shown in FIG. 6A, a 2 nm layer of Al₂O₃ is employed. The capping dielectric layer 640 can enhance charge retention within the underlying charge trapping layer 630 and reduces back injection to the gate during read and write operations. The material selection and thickness can be tuned to optimize trade-offs between MW, endurance, and retention.

The uppermost component of the FePFET-type memory structure 610 is gate electrode 650, which may include a metal or metal stack selected for suitable work function alignment and process compatibility. Materials may include, but are not limited to, tungsten (W), titanium nitride (TiN), tantalum nitride (TaN), or combinations thereof. The gate electrode 650 may be formed using physical vapor deposition (PVD), ALD, or CVD. The gate material may be chosen to provide proper electrostatic control over the channel and to support the desired switching characteristics across the ferroelectric and charge trapping layers.

FIG. 6B illustrates the transfer characteristics of the FePFET-type memory structure 610 incorporating the gate dielectric stack shown in FIG. 6A, including a 2 nm aluminum oxide (Al₂O₃) capping dielectric layer disposed above the charge trapping layer. The device is subjected to a #15 V programming pulse with a duration of 10 μs. Two threshold voltage (V<sub>TH</sub>) extraction conditions are illustrated: (1) using a read current level of 5 nA×W/L, yielding a MW of approximately 8.3 V; and (2) using a read current level of 100 nA×W/L, yielding a MW of approximately 12.8 V. These results demonstrate that the FePFET-type memory structure 610 achieves a highly tunable and expanded MW depending on the readout criteria. The observed enhancement in MW is attributable to both ferroelectric switching and effective gate-side charge trapping, the latter of which is aided by the presence of the Al₂O₃ layer that acts as a tunneling and retention control barrier.

FIG. 6C presents a contour map of the switching dynamics of the FePFET-type memory structure 610, illustrating the relationship between MW and programming pulse parameters. The vertical axis represents the pulse width applied during the write operation, ranging from 100 ns to 1 ms on a logarithmic scale. The horizontal axis represents the applied write voltages—V_{Reset} (negative polarity) on the left and V_{Set} (positive polarity) on the right. Each contour line corresponds to a specific MW level, enabling visualization of operating regions that produce minimal or maximal MW. The plot indicates that large MWs are achievable across a broad range of voltage amplitudes and pulse durations, with the most efficient programming occurring around ±12 V to ±14 V and pulse durations above 1 μs. Regions labeled “Break” represent boundary conditions beyond which device degradation or dielectric failure may occur. This analysis confirms that the FePFET-type memory structure 610 supports robust switching characteristics under high-speed programming conditions suitable for embedded and storage-class memory applications.

FIG. 6D illustrates a benchmarking summary comparing the performance metrics of the FePFET-type memory structure 610 with those of four representative FeFET-based memory designs reported using alternative approaches. The comparison highlights several attributes, including total gate stack height, required write voltage, write speed, and achievable MW.

The FePFET-type memory structure 610, incorporating a ferroelectric layer and charge trapping layer with an additional capping dielectric layer (e.g., Al₂O₃), achieves a compact stack height of approximately 15 nm, or 17 nm depending on the precise material configuration. This compares favorably with conventional implementations, many of which exceed 19-20 nm or are unspecified. A reduced stack height supports increased integration density and compatibility with advanced vertical NAND scaling.

In terms of programming voltage, the FePFET-type memory structure 610 demonstrates effective operation at relatively low write voltages, achieving a functional MW using write pulses as low as 11 V (or up to 15 V for extended performance). This is significantly lower than alternative implementations that typically require up to 16 V.

Write speed is also markedly improved. The FePFET-type memory structure 610 supports write pulse widths as short as 1 μs, which enables faster programming cycles. Some previously reported devices operate with sub-microsecond speeds, but often require trade-offs in MW or voltage.

The FePFET-type memory structure 610 achieves a MW of approximately 6 V-8 V under nominal conditions and as high as 8 V-13 V under extended write conditions. These values are competitive or superior to the MWs achieved in other large-memory-window FeFET devices, many of which report MWs in the range of 3 V-7 V.

Overall, the benchmarking results underscore the competitive advantage of the proposed MIFIS architecture used in the FePFET-type memory structure 610, particularly with respect to scalability, operating voltage, speed, and nonvolatile MW. The integrated gate-side injection and polarization switching mechanisms contribute to its high efficiency and make it a strong candidate for next-generation embedded and 3D storage applications.

### Terminology

The terminology used herein is for the purpose of describing particular embodiments only and is not intended to be limiting. As used in the description and appended claims, the singular forms “a,” “an,” and “the” include plural referents unless the context clearly indicates otherwise. The term “and/or” includes any and all combinations of one or more of the associated listed items. The term “or” should be understood to mean “and/or” except where explicitly stated otherwise or where the context clearly dictates a different interpretation.

As used herein, the term “comprise” and variants such as “comprises” and “comprising” are to be construed as inclusive, open-ended terms (i.e., “including, but not limited to”), and do not exclude additional, unrecited elements or method steps. The terms “consisting of” and “consisting essentially of” are to be interpreted as having their customary meanings as used in patent law. In some embodiments, “comprise” may include “consist essentially of” and/or “consist of.”

The term “about” generally indicates a margin of error or variation that would be understood by one of ordinary skill in the art. For example, “about” may refer to ±1%, ±2%, ±5%, ±10%, or ±20% of the stated value depending on context. Unless otherwise specified, any numerical value presented in this disclosure—whether or not it is qualified by the term “about”—should be interpreted as including reasonable variation due to fabrication tolerances, measurement error, or process-related variation. Similarly, the term “substantially” means largely, but not wholly, the same form, manner or degree, as would be understood by a person of ordinary skill in the art.

As used herein, the terms “disposed on,” “on,” “over,” “above,” “under,” or “beneath” refer to the relative placement of structural layers or components and may include both direct contact and indirect contact (i.e., with one or more intervening layers). These terms do not require direct physical contact unless explicitly stated. Similarly, terms such as “connected,” “coupled,” or any variant thereof, include direct and indirect connections or couplings, and the connection or coupling can be physical, logical, or functional, unless stated otherwise.

Terms referring to directionality (e.g., “top,” “bottom,” “upper,” “lower,” “vertical”) are used for convenience of description based on the orientation shown in example figures and do not imply a fixed or required device orientation. Layer “thickness” or “height” values provided herein may include reasonable fabrication tolerances, and may vary based on deposition technique or integration flow. Unless expressly stated otherwise, references to numeric ranges (e.g., thicknesses, voltages, durations) should be understood to encompass approximate, nominal, and design-target values within the expected process variation.

Conditional language, such as “can,” “could,” “may,” “might,” or similar expressions, unless specifically stated otherwise, is intended to convey that certain embodiments include, while others do not include, certain features, elements, or steps. Such language is not to be interpreted as requiring that all embodiments include the described features, elements, or steps, or that any logic for making determinations based on such conditions is required.

Conjunctive language such as “at least one of A, B, or C” should be interpreted to mean “A alone, B alone, C alone, or any combination thereof,” unless otherwise indicated. Likewise, expressions using the term “between” include both endpoints unless otherwise indicated.

Unless otherwise noted, all methods described herein can be performed in any suitable order and combination. Any or all of the features and functions described in the embodiments disclosed herein may be combined with one another, except where such combinations are mutually exclusive or logically incompatible as would be apparent to a person skilled in the art.

The use of headings and labels is for organizational convenience only and should not be construed to limit the scope of the disclosure or claims. Furthermore, features from different embodiments may be combined unless otherwise specified. It is understood that different embodiments may include features in different configurations or orders, and that such differences are supported by the disclosure and fall within the scope of the invention.

The terminology used herein, such as “configured to,” “adapted for,” and “arranged to,” serves to suggest that certain embodiments may incorporate particular circuit elements, configurations, or operational capabilities, while other embodiments may not. The inclusion of such terms does not imply that these elements, configurations, or capabilities are obligatory for any embodiment, nor does it indicate that specific logic exists for determining whether these elements, configurations, or operational capabilities are incorporated or executed in a given embodiment.

To reduce the number of claims, certain aspects of the invention are presented below in certain claim forms, but the applicant contemplates other aspects of the invention in any number of claim forms. Any claims intended to be treated under 35 U.S.C. § 112(f) will begin with the words “means for,” but use of the term “for” in any other context is not intended to invoke treatment under 35 U.S.C. § 112(f). Accordingly, the applicant reserves the right to pursue additional claims after filing this application, in either this application or in a continuing application.

What is claimed is:

1. A nonvolatile memory device comprising:
a semiconductor substrate;
a gate stack disposed on the semiconductor substrate, the gate stack comprising:
an interfacial dielectric layer disposed on the semiconductor substrate;
a ferroelectric dielectric layer disposed on the interfacial dielectric layer, the ferroelectric dielectric layer being configured to undergo polarization switching in response to an applied electric field;
a charge trapping layer disposed on the ferroelectric dielectric layer; and
a gate electrode disposed on the charge trapping layer,
wherein application of a programming pulse to the gate electrode generates an electric field across the ferroelectric dielectric layer,
wherein the electric field causes the polarization switching within the ferroelectric dielectric layer,
wherein the charge trapping layer is configured to receive charge from the gate electrode during application of a programming pulse,
wherein the polarization switching facilitates injection of charge from the gate electrode into the charge trapping layer, and
wherein the charge trapping layer is configured to retain the injected charge to contribute to a shift in threshold voltage of the nonvolatile memory device.

2. The device of claim 1, wherein the charge trapping layer comprises silicon nitride (SiNₓ).

3. The device of claim 1, wherein the ferroelectric dielectric layer comprises hafnium zirconium oxide (Hf_{0.5}Zr_{0.5}O₂).

4. The device of claim 1, wherein the gate stack further comprises a capping dielectric layer disposed between the charge trapping layer and the gate electrode, wherein the capping dielectric layer is configured to inhibit charge leakage from the charge trapping layer to the gate electrode.

5. The device of claim 4, wherein the capping dielectric layer comprises aluminum oxide (Al₂O₃).

6. The device of claim 4, wherein the capping dielectric layer has a thickness in the range of 1 nm to 5 nm.

7. The device of claim 1, wherein the charge trapping layer is configured to retain gate-injected charge during polarization switching of the ferroelectric dielectric layer, the retained charge contributing to an increased threshold voltage shift relative to polarization switching alone.

8. The device of claim 1, wherein the gate stack is configured to establish multiple stable threshold voltage states through a combination of ferroelectric polarization switching and gate-side charge storage.

9. The device of claim 1, wherein the gate stack consists of, in order from the substrate upward the interfacial dielectric layer, the ferroelectric dielectric layer, the charge trapping layer, and the gate electrode.

10. The device of claim 1, wherein the ferroelectric dielectric layer has a thickness between 5 nm and 15 nm, and the charge trapping layer has a thickness between 2 nm and 8 nm, and wherein the interfacial dielectric layer comprises silicon oxide (SiOₓ) having a thickness of approximately 1 nm.

11. The device of claim 1, wherein the gate stack is configured to support at least three distinct programmable threshold voltage levels.

12. The nonvolatile memory device of claim 1, wherein the charge trapping layer and the ferroelectric dielectric layer are configured such that a combination of gate-injected charge retention and ferroelectric polarization switching produces a MW greater than would result from ferroelectric polarization switching alone.

13. The nonvolatile memory device of claim 1, wherein the nonvolatile memory device further comprises source and drain regions formed in the semiconductor substrate, the gate stack being disposed over a channel region between the source and drain regions.

14. The nonvolatile memory device of claim 1, wherein the charge trapping layer and the ferroelectric dielectric layer are configured such that application of a first programming pulse results in a first MW, and application of a second programming pulse, having a different amplitude or duration than the first programming pulse, results in a second MW different from the first MW.

15. The device of claim 1, wherein the gate electrode is configured to receive a plurality of programming pulses of differing amplitude or duration, and wherein a cumulative effect of the programming pulses results in incremental adjustment of threshold voltage, enabling storage of multiple logic states within a single memory cell.

16. A method of programming a nonvolatile memory device, the method comprising:
providing a memory device comprising:
a semiconductor substrate;
a gate stack disposed on the semiconductor substrate, the gate stack comprising:
an interfacial dielectric layer;
a ferroelectric dielectric layer disposed on the interfacial dielectric layer, the ferroelectric dielectric layer being configured to undergo polarization switching in response to an electric field;
a charge trapping layer disposed on the ferroelectric dielectric layer; and
a gate electrode disposed on the charge trapping layer; and
applying a programming pulse to a gate electrode,
wherein the programming pulse generates an electric field across the ferroelectric dielectric layer,
wherein the electric field causes polarization switching in the ferroelectric dielectric layer,
wherein the polarization switching facilitates injection of charge from the gate electrode into the charge trapping layer, and
wherein the injected charge is retained in the charge trapping layer and contributes to a threshold voltage shift of the memory device.

17. The method of claim 16, wherein the programming pulse is first programming pulse, and wherein the method further comprises:
applying a second programming pulse to the gate electrode, the second programming pulse having a different voltage amplitude or duration than the first programming pulse,
wherein the first and second programming pulses establish distinct threshold voltage states in the memory device.

18. The method of claim 16, wherein the gate stack further comprises a capping dielectric layer disposed between the charge trapping layer and the gate electrode, wherein the capping dielectric layer is configured to inhibit charge leakage from the charge trapping layer to the gate electrode, and wherein the capping dielectric layer comprises aluminum oxide (Al₂O₃).

19. The method of claim 16, wherein the ferroelectric dielectric layer comprises hafnium zirconium oxide (Hf_{0.5}Zr_{0.5}O₂).

20. The method of claim 16, wherein the charge trapping layer and the ferroelectric dielectric layer are configured such that the combination of gate-injected charge retention and ferroelectric polarization switching produces a MW greater than would result from ferroelectric polarization switching alone.
